(19) United States
(12) Patent Application Publication
(10) Pub. No.: US 2026/0366826 A1
(43) Pub. Date: Nov. 19, 2026

(54) HEAT SINK

(71) Applicant: Telefonaktiebolaget LM Ericsson (publ), Stockholm (SE)

(72) Inventors: Yigit AKKUS, Huddinge (SE); Stevin VAN WYK, Täby (SE)

(21) Appl. No.: 19/471,013

(22) PCT Filed: Apr. 3, 2023
(86) PCT No.: PCT/SE2023/050296

§ 371 Date: Sep. 30, 2025

(51) Int. Cl. F28F 3/04

(52) U.S. Cl. CPC F28F 3/04; F28F 2215/04

(57) ABSTRACT

A heat sink includes a substantially planar base and a first set of fins disposed on a first side of the base. Each fin has a length parallel to a plane of the base. One or more first fins of the first set of fins includes a first heat transfer type and one or more second fins of the first set of fins includes a second heat transfer type different to the first heat transfer type. The length of the one or more first fins is longer than the length of the one or more second fins.

### TECHNICAL FIELD

Embodiments of the present disclosure relate to heat sinks, and particularly to heat sinks comprising one or more first fins comprising a first heat transfer type and one or more second fins comprising a second heat transfer type.

### BACKGROUND

Two-phase passive heat spreading techniques attract the attention of thermal scientists in academia and researchers in industry because of their potential in thermal management. The term “two-phase” refers to the existence of both liquid and vapor phases of a working fluid. The term “passive heat spreading” refers to the fact that there is no external energy is used to drive the cooling system, meaning no fans or pumps are used to circulate the working fluid. In two-phase passive heat spreading techniques, concurrent evaporation and condensation can take place near regions where heat is added to and removed from the system, respectively. These regions may be referred to as “evaporator” and “condenser”, respectively. The fluid transfer between the evaporator and condenser may be driven by one or a combination of the following physical phenomena: gravity, buoyancy, diffusion, capillarity, fluid instability, liquid-vapor phase change dynamics.

Different two-phase heat spreading techniques utilize different driving forces. For example, in thermosiphons (also referred to as “thermosyphons”), natural convection (which involves gravity and buoyancy accompanied by the liquid-vapor phase change dynamics) circulates the fluid. The principle of the thermosiphon is utilized in various heating and cooling applications such as boilers, heat pumps, loop thermosiphons (LTS) etc. Another technique is the use of a heat pipe, as named by its inventor Grover (U.S. Pat. No. 3,229,759A), which utilizes capillarity as the origin of a major driving force to circulate the fluid. Different heat pipe applications have been proposed over the years such as vapor chambers, variable conductance heat pipes, and pulsating heat pipes (PHP)/oscillating heat pipes etc. (Reay et al., Heat pipes: theory, design and applications, Butterworth-Heinemann, ISBN 0080982794, 9780080982793, 2013).

Among thermosiphon applications, loop thermosiphons, where vapor and liquid travel in the same direction around a loop without experiencing contour flow and undesirable shear stress in between thereof, are preferred in high heat flux applications. An example loop thermosiphon 100 design is illustrated in FIG. 1. The loop thermosiphon 100 comprises a looped conduit 102, an evaporator 104, and a condenser 106. The looped conduit 102 is partly filled with a working fluid. In the evaporator 104, the working fluid evaporates into a vapour 110. The expanding vapor phase pushes batches of the working fluid towards a condenser 106. This mechanism may be referred to as the “bubble lift” principle. In the condenser 106, the vapor 110 condenses into a liquid 108, and the conduit is filled by a liquid phase that is driven to return to the evaporator 104 by gravitational force.

Among heat pipe applications, pulsating heat pipes do not use a wick structure to circulate a working fluid. An example pulsating heat pipe 200 design is illustrated in FIG. 2. The pulsating heat pipe 200 comprises a serpentine channel 202 of capillary dimension, evaporation regions 204, and condensation regions 206. The serpentine channel 202 is evacuated and partially filled with a working fluid (Reay et al., Heat pipes: theory, design and applications, Butterworth-Heinemann, ISBN 0080982794, 9780080982793, 2013). Surface tension results in the formation of slugs of liquid 208 located between bubbles of vapor 210. Expansion of the vapor bubbles 210 at the evaporation regions 204 and contraction of the vapor bubbles 210 (at the condensation regions 206) results in movement of the working fluid along the capillary conduits 202. This mechanism is first described by Akachi in 1990 (U.S. Pat. No. 4,921,041A). The efficiency of a pulsating heat pipe 200 at transferring energy from the evaporation regions 204 to the condensation regions 206 is determined, in part, by the number of turns of the serpentine channel 202.

Both loop thermosiphons and pulsating heat pipes can be embedded in flat plates (CN106455431A, KR20130111035A). These may be referred to as LTS-embedded fins and PHP-embedded fins, respectively. Doing so can produce fins with higher efficiency compared to solid fins made of typical engineering metals. Fins can be attached to a base metal with different methods (welding, brazing, press fitting etc.) to create a heat sink, such as a straight-fin heat sink or a V-fin heat sink.

FIG. 3 illustrates a straight-fin heat sink 300 design. The straight-fin heat sink 300 comprises a base 302 and an array of fins 304 which are disposed on the base 302 and positioned parallel to a direction of gravitational force exerted on components of the straight-fin heat sink 300 (sometimes referred to as a “gravity vector”), \vec{g}. If thermosiphons (e.g., the looped thermosiphon 100 of FIG. 1) are embedded within these fins, the maximum driving force exerted on the working fluid (also referred to as the “gravitational head”, H_{g}) is proportional to the distance between the lowermost and uppermost levels of the fins. For example, for the first fin in the fin array 304 of the straight-fin heat sink, the gravitational head is designated

$${H}_{g}^{S F 1} .$$

Since all the fins in the fin array 304 are identical and have the same positioning with respect to the gravity vector, the gravitational head is the same for all fins of the fin array 304. Moreover, this gravitational head is the maximum possible gravitational head for a given fin dimension as the fins are positioned parallel to the gravity vector, which maximizes the gravitational head. Therefore, for the fins in FIG. 3,

$${H}_{g}^{S F 1} = {H}_{g}^{SF , max} .$$

FIG. 4 illustrates a V-fin heat sink design 400. The V-fin heat sink 400 comprises a base 402 and two symmetrical tilted fin arrays 404, 406, wherein each fin of the two symmetrical fin arrays 404, 406 is tilted with respect to a gravity vector, \vec{g}. The two symmetrical fin arrays 404, 406 are separated by a mid-channel (e.g., an air channel). If thermosiphons are embedded within these fins (e.g., looped thermosiphons 100 of FIG. 1), the maximum driving force/gravitational head that could be generated is proportional to the distance between the lowermost and uppermost levels of the fins. For example, for the uppermost three fins in each fin array 404, 406, the gravitational head is respectively designated

$${H}_{g}^{VF 1} , {H}_{g}^{VF 2} , and {H}_{g}^{VF 3} .$$

Since these three fins have different lengths, the gravitational head is different for each fin. That is, the longer fins have a higher gravitational head

$$( e . i . , {H}_{g}^{V F 1} < {H}_{g}^{V F 2} < {H}_{g}^{V F 3} ) .$$

Since the longest fins on the heat sink have the length of the third fin,

$${H}_{g}^{V F 3}$$

is the maximum possible gravitational head for a thermosiphon embedded within a fin positioned in the V-fin heat sink design 400 of FIG. 4. Therefore, for the fins of FIG. 4,

$${H}_{g}^{V F 3} = {H}_{g}^{VF , max} .$$

### SUMMARY

There currently exist certain challenges. Heat-generating components used in M-MIMO systems (e.g., application-specific integrated circuits (ASICs), memory chips, processing circuitry) can reach undesirable temperatures if not actively cooled, reducing their performance and/or life expectancy. One such method of cooling is disposing heat sinks, such as those illustrated in FIGS. 3 and 4, on a surface of the heat-generating component, such that heat energy is removed from the heat-generating component and transferred to the surrounding air via the heat sink. Improving the heat-transfer performance of heat sinks can therefore further improve the performance and/or life expectancy of heat-generating components.

Embodiments of the present disclosure relate to heat sinks comprising a combination of heat transfer types/technologies such that they have enhanced performance (e.g., efficiency) for a given set of properties of (e.g., fin material, fin geometry, fin orientation with respect to a gravity vector, etc).

According to a first aspect of the present disclosure, a heat sink comprises: a substantially planar base; and a first set of fins disposed on a first side of the base. Each fin has a length parallel to a plane of the base. One or more first fins of the first set of fins comprise a first heat transfer type and one or more second fins of the first set of fins comprise a second heat transfer type different to the first heat transfer type. The length of the one or more first fins is longer than the length of the one or more second fins.

According to a second aspect of the present disclosure, a device comprises a processing apparatus and one or more heat sinks according to the first aspect of the present disclosure. The one or more heat sinks interface with one or more components of the processing apparatus.

Embodiments of the present disclosure describe a heat sink which can efficiently transfer heat energy away from a heat-generating component with which it may interface, thus enabling the efficient cooling of the heat-generating component. Therefore, embodiments of the present disclosure enable improved thermal management of heat-generating components (e.g., M-MIMO products) without the use of active cooling methods such as fan cooling.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 is a schematic diagram illustrating a loop thermosiphon;

FIG. 2 is a schematic diagram illustrating a pulsating heat pipe;

FIG. 3 is a schematic diagram illustrating a straight fin heat sink;

FIG. 4 is a schematic diagram illustrating a V-fin heat sink;

FIG. 5 is a schematic diagram illustrating a first heat sink design in accordance with some embodiments;

FIG. 6 is a schematic diagram illustrating a second heat sink design in accordance with some embodiments;

FIG. 7 is a schematic diagram illustrating a device in accordance with some embodiments.

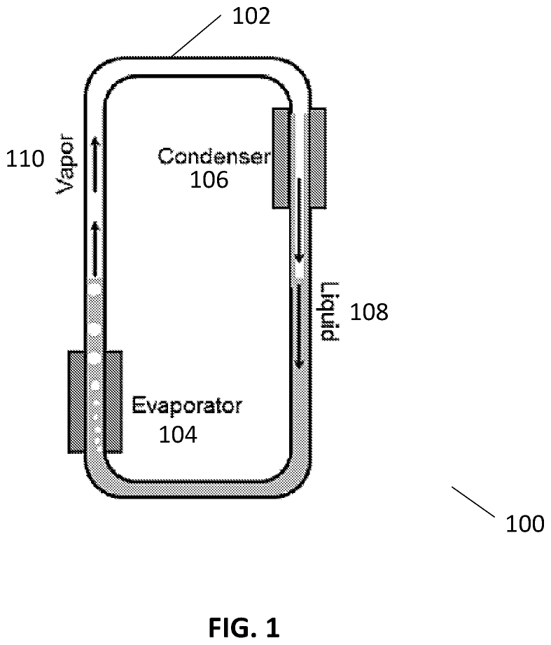

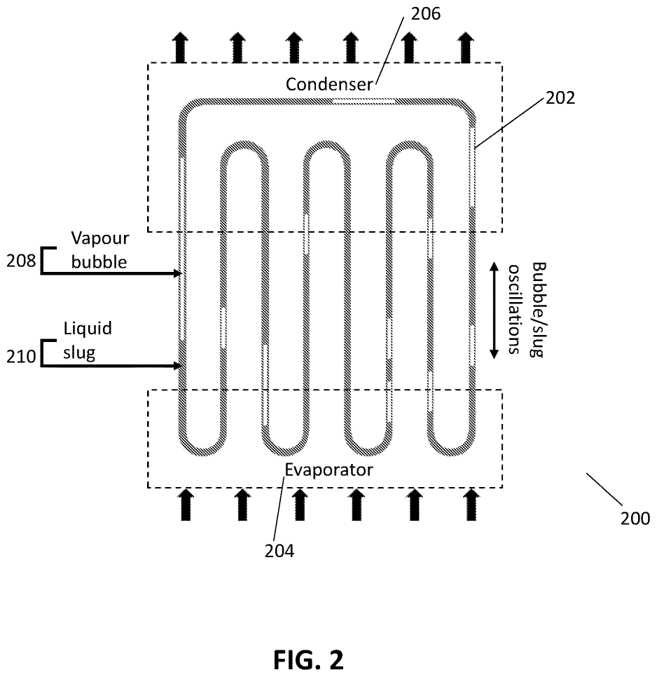

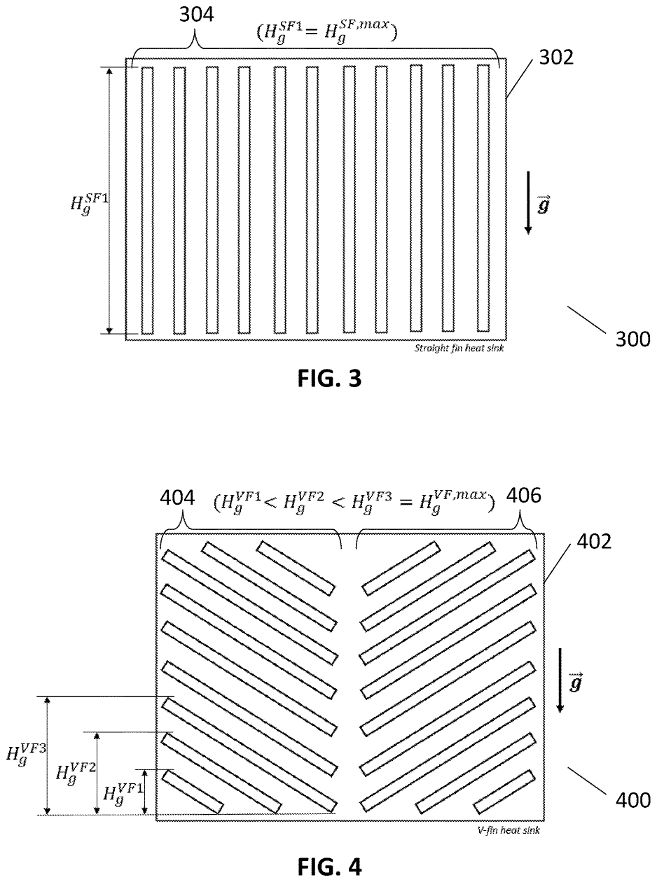

### DETAILED DESCRIPTION

Some of the embodiments contemplated herein will now be described more fully with reference to the accompanying drawings. Other embodiments, however, are contained within the scope of the subject matter disclosed herein. The disclosed subject matter should not be construed as limited to only the embodiments set forth herein; rather, these embodiments are provided by way of example to convey the scope of the subject matter to those skilled in the art.

As the operation of a thermosiphon is dependent upon gravity, the efficiency of thermosiphons is dependent upon the positioning of the thermosiphons with respect to a gravity vector. In that sense, straight fin heat sink designs can be more suited to accommodating thermosiphon-embedded fins compared to V-fin heat sink designs, as straight fin heat sinks can have a higher gravitational head per fin for a given fin dimension

$$( e . i . , {H}_{g}^{SF , max} > {H}_{g}^{VF , max} ) .$$

However, straight fin heat sinks can suffer from reduced heat removal efficiency at the uppermost levels of the fins. This is because air at the lowermost levels of the fins may be heated by the fins themselves. This heated air can rise to the uppermost levels of the fins where it transfers heat energy to the condensing regions of the fins, reducing the heat removal efficiency of these regions.

On the other hand, with V-fin heat sinks, whilst air may still be heated at the lowermost levels of the fins, this heated air can rise and be directed away from the uppermost levels of the fins due to the tilted orientation of the fins. This allows for a feed of fresh air to enter the heat sink through the channel(s) located between the arrays of fins.

Thus, in comparison to the straight fin heat sink, air can circulate easily through the V-fin heat sink, providing a cooling effect. As such, in some examples, using a V-fin heat sink design rather than a straight fin heat sink design results in lower temperatures of components located at the uppermost levels of the heat sink.

In contrast to loop thermosiphons, heat pipes can operate without the assistance of gravity (and can even operate against gravity). Thus, PHP-embedded fins are suitable to be used in both straight-fin heat sink and V-fin heat sink designs. However, pulsating heat pipes are sometimes less efficient at transferring heat than thermosiphons (Mantelli, Thermosyphons and heat pipes: theory and applications, Springer International Publishing, 2021), for example due to higher viscous losses during circulation of the working fluid.

Therefore, for certain configurations of fins (e.g., straight fin heat sink designs), LTS-embedded fins are more efficient at transferring heat away form a base of a heat sink than PHP-embedded fins (even when the loop thermosiphons use a smaller number of loops/turns than the pulsating heat pipes).

However, for other configurations of fins (e.g., configurations resulting in a small gravitational head being exerted on the working fluid), LTS-embedded fins are less efficient at transferring heat away form a base of a heat sink than PHP-embedded fins.

Embodiments of the present disclosure utilize multiple two-phase heat spreading techniques simultaneously to create a hybrid heat sink design that has improved heat transfer performance compared to heat sinks that adopt a single two-phase heat spreading technique. For example, embodiments of the present disclosure may be used as part of a hybrid V-fin heat sink design, wherein each fin of the heat sink comprises one of three forms of flat plate structure (e.g., a plain solid fin, a PHP-embedded fin, or an LTS-embedded fin).

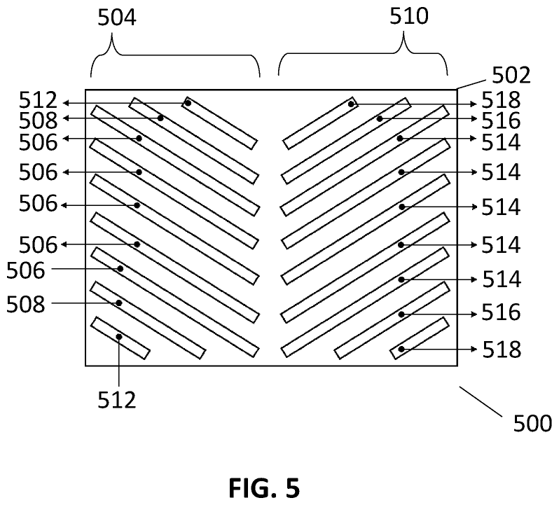

FIG. 5 illustrates a first heat sink design 500 according to embodiments of the present disclosure. In some embodiments, the heat sink may be a component of a M-MIMO system, a remote radio system, and/or any type of mast-mounted radio system.

The heat sink comprises a substantially planar base 502. In some embodiments, the base 502 may be made from a first thermally conductive material which is efficient at absorbing heat energy, such as a metal (e.g., aluminium, copper, etc).

The heat sink also comprises a first set of fins 504 disposed on a first side of the base 502. In some embodiments, a second side of the base (opposite the first side of the base) may be adapted to interface with a surface of a heat-generating component, such that heat energy may be transferred from the heat-generating component to the heat sink.

Each fin (of the first set of fins 504) has a length parallel to a plane of the base 502. For example, each fin may be considered to have a height perpendicular to the plane of the base and a thickness perpendicular to its height and perpendicular to its length. As seen in FIG. 5, the first set of fins 504 may be arranged such that they do not intersect one another (e.g., they may be substantially parallel to one another).

In some embodiments, the first set of fins 504 may be substantially planar (e.g., each fin may be a plate which is substantially rectangular in shape). As such, in some embodiments, the length of each fin of the first set of fins 504 may parallel to both a plane of the base and a plane of the fin.

One or more first fins 506 of the first set of fins 504 comprise a first heat transfer type and one or more second fins 508 of the first set of fins comprise a second heat transfer type different to the first heat transfer type. The length of the one or more first fins 506 is longer than the length of the one or more second fins 508. As such, the one or more first fins 506 are able to have a greater gravitational head per fin in comparison to the one or more second fins 508 when the heat sink is in use.

A heat transfer type may also be referred to as a heat transfer technology, and can be considered to describe the principal mechanism/technology by which heat energy is transferred through/across a fin comprising that heat transfer type. The principal mechanism may utilise heat convection and/or heat conduction for transferring energy through/across the fin.

In some embodiments of FIG. 5, the first heat transfer type may comprise a loop thermosiphon and the second heat transfer type may comprise a solid plate (which may also be referred to as a “solid fin” or a “solid metal plate” in some examples). The solid plate may be made of a second thermally conductive material which is efficient at absorbing heat energy, such as a metal (e.g., aluminium, copper, etc). For example, in one embodiment, the first thermally conductive material and the second thermally conductive material may be the same material (e.g., the base and the solid plates may be produced as a single part via die casting and/or machining). In another embodiment, the first thermally conductive material and the second thermally conductive material may be different materials. For example, the second thermally conductive material may have a higher thermal conductivity than the first thermally conductive material (e.g., the first thermally conductive material may be aluminium and the second thermally conductive material may be copper).

In other words, in some embodiments of FIG. 5, the shorter fins disposed on the base 502 of the heat sink may be solid plates as their gravitational head is too small for them to be efficient LTS-embedded fins. Similarly, their lengths are too short for them to accommodate an adequate number of PHP-channel turns for them to be efficient PHP-embedded fins. On the other hand, longer fins disposed on the base 502 may be LTS-embedded fins since their gravitational head is sufficient for them to function efficiently as LTS-embedded fins and their predicted performance at transferring heat energy away from the heat sink base 502 is better in comparison to a PHP-embedded fin or a solid plate.

In other embodiments of FIG. 5, the first heat transfer type may comprise a pulsating heat pipe and the second heat transfer type may comprise a solid plate. In other words, shorter fins disposed on the base 502 of the heat sink may be solid plates as their gravitational head is too small for them to be efficient LTS-embedded fins. Similarly, their lengths are too short for them to accommodate an adequate number of PHP-channel turns for them to be efficient PHP-embedded fins. On the other hand, longer fins disposed on the base 502 may be PHP-embedded fins since their gravitational head is not sufficient for them to function efficiently as LTS-embedded fins and their predicted performance at transferring heat energy away from the heat sink base 502 is better in comparison to an LTS-embedded fin or a solid plate.

In other embodiments of FIG. 5, the first heat transfer type may comprise a loop thermosiphon and the second heat transfer type may comprise a pulsating heat pipe. In other words, shorter fins disposed on the base 502 of the heat sink may be PHP-embedded fins as their gravitational head is too small for them to be efficient LTS-embedded fins and their predicted performance at transferring heat energy from the heat sink base 502 is better in comparison to an LTS-embedded fin or a solid plate. On the other hand, longer fins disposed on the base 502 may be LTS-embedded fins since their gravitational head is sufficient for them to function efficiently as LTS-embedded fins and their predicted performance at transferring heat energy away from the heat sink base 502 is better in comparison to a PHP-embedded fin or a solid plates.

In other embodiments, the one or more third fins 512 of the first set of fins 504 of FIG. 5 may comprise a third heat transfer type. The third heat transfer type is different to the first heat transfer type and the second heat transfer type, and the length of the one or more second fins 508 is longer than the length of the one or more third fins 512. For example, the first heat transfer type may comprise a loop thermosiphon, the second heat transfer type may comprise a pulsating heat pipe, and the third heat transfer type may comprise a solid plate (e.g., the solid plate discussed above in relation to FIG. 5).

In other words, shorter fins disposed on the base 502 of the heat sink may be solid plates as their gravitational head is too small for them to be efficient LTS-embedded fins and/or their lengths are too short for them to accommodate an adequate number of PHP-channel turns for them to be efficient PHP-embedded fins. On the other hand, longer fins disposed on the base 502 may be PHP-embedded fins since their gravitational head is not sufficient for them to function efficiently as LTS-embedded fins and their predicted performance at transferring heat energy from the heat sink base 502 is better in comparison to an LTS-embedded fin or a solid plate. The longest fins disposed on the base 502 may be LTS-embedded fins since their gravitational head is sufficient for them to function efficiently as LTS-embedded fins and their predicted performance at transferring heat energy away from the heat sink base 502 is better in comparison to a PHP-embedded fin or a solid plate.

In some embodiments, the first heat sink design 500 may further comprise a second set of fins 510 disposed on the first side of the base 502. A s with the first set of fins 504, each fin of the second set of fins 510 may have a length parallel to a plane of the base 502.

For example, each fin of the second set of fins 510 may be considered to have a height perpendicular to the plane of the base and a thickness perpendicular to its height and perpendicular to its length. As seen in FIG. 5, the second set of fins 510 may be arranged such that they do not intersect one another (e.g., they may be substantially parallel to one another).

In some embodiments, the second set of fins 510 may be substantially planar (e.g., each fin may be a plate which is substantially rectangular in shape). As such, in some embodiments, the length of each fin of the second set of fins 510 may be parallel to both a plane of the base and a plane of the fin.

In some embodiments, one or more fourth fins 514 of the second set of fins 510 may comprise the first heat transfer type comprised in the one or more first fins 506, whilst one or more fifth fins 516 of the second set of fins 510 may comprise the second heat transfer type comprised in the one or more second fins 508. The length of the one or more fourth fins 514 is longer than the length of the one or more fifth fins 516.

In some embodiments where a third heat transfer type is comprised in one or more third fins 512 of the first set of fins 504, one or more sixth fins 518 of the second set of fins 510 may comprise the third heat transfer type. The length of the one or more fifth fins 516 is longer than the length of the one or more sixth fins 518.

In some embodiments, the first set of fins 504 and the second set of fins 510 may be arranged such that an air channel is formed between the first set of fins 504 and the second set of fins 510. For example, the first set of fins 504 may be confined to a first substantially rectangular region on the first side of the base 502, and the second set of fins 510 may be confined to a second substantially rectangular region on the first side of the base 502, such that a gap exists between ends of the first set of fins 504 and ends of the second set of fins 510. This configuration would allow cool air to flow over the base 502 and past the ends of the first set of fins 504 and ends of the second set of fins 510, improving the efficiency at which the fins of the heat may transfer heat energy away from the base 502.

In some embodiments, the lengths of the first set of fins 504 may be at an angle of 5-85 degrees to a side of the first substantially rectangular region and/or the lengths of the second set of fins 510 may be at an angle of 5-85 degrees to a side of the second substantially rectangular region. In some embodiments, the lengths of the first set of fins are at an angle of 5-85 degrees to the lengths of the second set of fins. Such arrangements may in some examples result in a V-fin heat sink design.

In some embodiments, the first heat sink design 500 may comprise one or more additional sets of fins corresponding to either one of the first set of fins 504 or the second set of fins 510, such that multiple sets of fins are disposed on the base 502 in a substantially parallel manner with an air channel being formed in between each set.

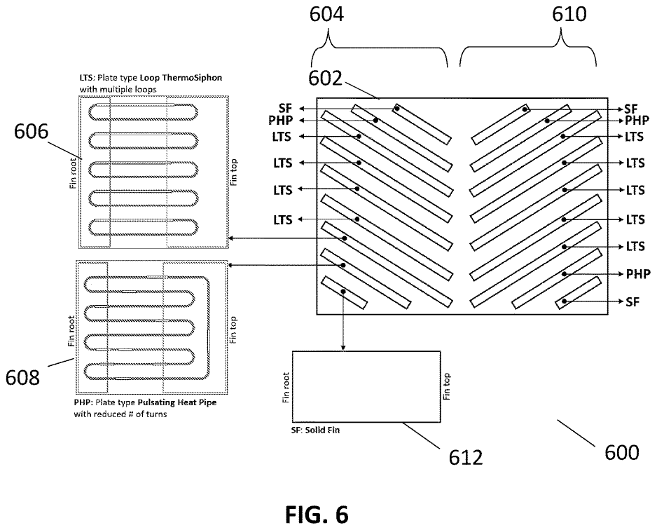

FIG. 6 illustrates a second heat sink design 600 according to embodiments of the present disclosure. As with embodiments of the first heat sink design 500, the second heat sink design 600 comprises a base 602 and a first set of fins 604 (comprising one or more first fins 606, one or more second fins 608, and one or more third fins 612). The heat sink further comprises a second set of fins 610 (comprising one or more fourth fins, one or more fifth fins, and one or more sixth fins). As these features correspond to those discussed in relation to FIG. 5, a duplicate description of their functionality is omitted.

As seen in FIG. 6, the shortest fins 612 are solid fins and the longest fins 606 comprise loop thermosiphons. Fins which are a length in between that of the shortest and longest fins (“medium length fins”) 608 comprise pulsating heat pipes.

When either of the first heat sink design 500 or the second heat sink design 600 are in use (i.e., interfacing with a heat-generating component), the base will be substantially parallel to a gravity vector. Therefore, it can be appreciated from FIGS. 5 and 6 that the longest fins 506, 606 will have the greatest gravitational head per fin and are therefore suited to being LTS-embedded fins (whose efficiency is dependent upon gravity). The medium length fins 508, 608 will have a smaller gravitational head per fin than the longest fins 506, 606 and are therefore suited to being PHP-embedded fins (whose efficiency is not dependent upon gravity but upon a number of turns in the PHP-channel). The shortest length fins 512, 612 will have a smaller gravitational head than both the longest fins 506, 606 and the medium length fins 508, 608 and are therefore suited to being solid plates (whose efficiency is not dependent upon gravity or a number of turns in a PHP-channel).

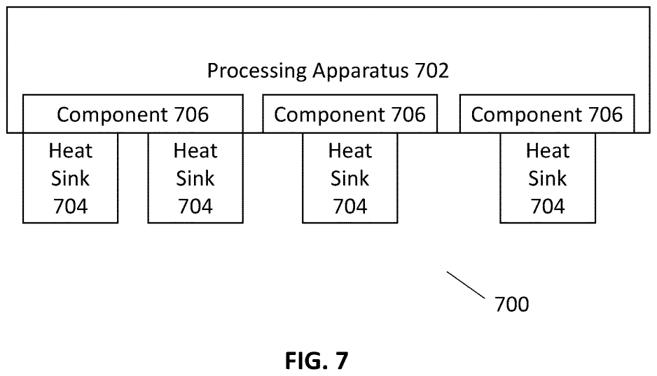

FIG. 7 illustrates a device 700 according to embodiments of the present disclosure. The device 700 comprises a processing apparatus 702 and one or more heat sinks 704. The one or more heat sinks correspond to the heat sinks of the embodiments of FIGS. 5 and 6 discussed above. As seen in FIG. 7, the one or more heat sinks 704 interface with one or more components 706 (e.g., one or more ASICs) of the processing apparatus 702.

In some embodiments, the one or more components 706 comprise one or more processors (e.g., a M-MIMO radio transceivers, one or more remote radio transceivers, and/or one or more radio transceivers of a mast-mounted radio system). As such, the one or more heat sinks 704 can transfer heat energy away from the one or more components 706, improving their performance and increasing their operating life expectancy.

It should be noted that the above-mentioned examples illustrate rather than limit the disclosure, and that those skilled in the art will be able to design many alternative embodiments without departing from the scope of the appended embodiments. The word “comprising” does not exclude the presence of elements or steps other than those listed in an embodiment or claim, “a” or “an” does not exclude a plurality, and a single processor or other unit may fulfil the functions of several units recited in the embodiments. Any reference signs in the claims shall not be construed so as to limit their scope.

1. A heat sink comprising:
a substantially planar base;
a first set of fins disposed on a first side of the base, each fin having a length parallel to a plane of the base; and
one or more first fins of the first set of fins comprising a first heat transfer type and one or more second fins of the first set of fins comprising a second heat transfer type different to the first heat transfer type, the length of the one or more first fins being longer than the length of the one or more second fins.

2. The heat sink according to claim 1, wherein each fin of the first set of fins has a height perpendicular to the plane of the base.

3. The heat sink according to claim 2, wherein each fin of the first set of fins has a thickness perpendicular to its height and perpendicular to its length.

4. The heat sink according to claim 1, wherein the first set of fins are one or both substantially planar and substantially parallel.

5. The heat sink according to claim 1, wherein:
the first heat transfer type comprises a loop thermosiphon and the second heat transfer type comprises a pulsating heat pipe; or
the first heat transfer type comprises a pulsating heat pipe and the second heat transfer type comprises a solid plate; or
the first heat transfer type comprises a loop thermosiphon and the second heat transfer type comprises a solid plate.

6.-32. (canceled)

33. The heat sink according to claim 5 wherein the base is made from a first thermally conductive material and the solid plate is made from a second thermally conductive material.

34. The heat sink according to claim 33, wherein:
the first thermally conductive material and the second thermally conductive material are the same material; or
the first thermally conductive material and the second thermally conductive material are different materials, and wherein the second thermally conductive material has a higher thermal conductivity than the first thermally conductive material.

35. The heat sink according to claim 1, wherein one or more third fins of the first set of fins comprises a third heat transfer type, wherein the third heat transfer type is different to the first heat transfer type and the second heat transfer type, and wherein the length of the one or more second fins is longer than the length of the one or more third fins.

36. The heat sink according to claim 35, wherein the first heat transfer type comprises a loop thermosiphon, the second heat transfer type comprises a pulsating heat pipe, and the third heat transfer type comprises a solid plate.

37. The heat sink according to claim 36, wherein the base is made from a first thermally conductive material and the solid plate is made from a second thermally conductive material.

38. The heat sink according to claim 37, wherein:
the first thermally conductive material and the second thermally conductive material are the same material; or
the first thermally conductive material and the second thermally conductive material are different materials, and wherein the second thermally conductive material has a higher thermal conductivity than the first thermally conductive material.

39. The heat sink according to claim 1, the heat sink further comprising a second set of fins disposed on the first side of the base, each fin having a length parallel to the plane of the base.

40. The heat sink according to claim 39, wherein an air channel is formed between the first set of fins and the second set of fins.

41. The heat sink according to claim 39, wherein the second set of fins have a height perpendicular to the plane of the base.

42. The heat sink according to claim 41, wherein each fin of the second set of fins has a thickness perpendicular to its height and perpendicular to its length.

43. The heat sink according to claim 41, wherein the first set of fins are confined to a first substantially rectangular region on the first side of the base and the second set of fins are confined to a second substantially rectangular region on the first side of the base.

44. The heat sink according to claim 43, wherein the lengths of the first set of fins are at an angle of 5-85 degrees to a side of the first substantially rectangular region.

45. The heat sink according to claim 43, wherein the lengths of the second set of fins are at an angle of 5-85 degrees to a side of the second substantially rectangular region.

46. The heat sink according to claim 39, wherein the lengths of the first set of fins are at an angle of 5-85 degrees to the lengths of the second set of fins.

47. The heat sink according to claim 39, wherein the second set of fins are one or both substantially planar and substantially parallel.
